(19) United States
(12) Patent Application Publication
(10) Pub. No.: US 2019/0212174 A1
(43) Pub. Date: Jul. 11, 2019

(54) SENSOR TEMPERATURE REGULATION

(71) Applicant: Ford Global Technologies, LLC, Dearborn, MI (US)

(72) Inventors: Venkatesh Krishnan, Canton, MI (US); Segundo Baldovino, Novi, MI (US); James Pizzimenti, Carleton, MI (US); Rashaun Phinisee, Ypsilanti, MI (US)

(73) Assignee: Ford Global Technologies, LLC, Dearborn, MI (US)

(21) Appl. No.: 15/866,543

(22) Filed: Jan. 10, 2018

(51) Int. Cl. G01D 11/24; H05K 7/20; G01K 7/02; G01K 1/14; G01K 1/12; B60R 11/00

(52) U.S. Cl. CPC G01D 11/245; H05K 7/20209; B60R 2011/004; G01K 1/14; G01K 1/12; G01K 7/02

(57) ABSTRACT

A sensor assembly includes a housing defining a cavity that includes a plurality of sensors, a semipermeable fabric covering an opening in the cavity, a fan positioned to direct airflow through the opening, and a controller programmed to activate the fan upon determining that a temperature of at least one sensor is above a threshold.

### BACKGROUND

Vehicle, such as autonomous or semi-autonomous vehicles, typically include a variety of sensors. Some sensors detect internal states of the vehicle, for example, wheel speed, wheel orientation, and engine and transmission variables. Some sensors detect the position or orientation of the vehicle, for example, global positioning system (GPS) sensors; accelerometers such as piezo-electric or microelectromechanical systems (MEMS); gyroscopes such as rate, ring laser, or fiber-optic gyroscopes; inertial measurements units (IMU); and magnetometers. Some sensors detect the external world, for example, radar sensors, scanning laser range finders, light detection and ranging (LIDAR) devices, and image processing sensors such as cameras. A LIDAR device detects distances to objects by emitting laser pulses and measuring the time of flight for the pulse to travel to the object and back. Some sensors are communications devices, for example, vehicle-to-infrastructure (V2I) or vehicle-to-vehicle (V2V) devices. Sensor operation can be affected by temperature, e.g., a sensor that is too hot may not operate properly.

### BRIEF DESCRIPTION OF THE DRAWINGS

FIG. 1 is a side view of an example vehicle with a sensor assembly.

FIG. 2 is a perspective view of the sensor assembly of FIG. 1.

FIG. 3 is a side view of the sensor assembly of FIG. 1.

FIG. 4 is a rear view of the sensor assembly of FIG. 1.

FIG. 5 is a top view of a cavity of a housing of the sensor assembly of FIG. 1.

FIG. 6 is a block diagram of a control system for the sensor assembly of FIG. 1.

FIG. 7 is a process flow diagram of an example process for regulating the temperatures of sensors of the sensor assembly of FIG. 1.

### DETAILED DESCRIPTION

A sensor assembly includes a housing defining a cavity that includes a plurality of sensors, a semipermeable fabric covering an opening in the cavity, a fan positioned to direct airflow through the opening, and a controller programmed to activate the fan upon determining that a temperature of at least one sensor is above a threshold.

The sensor assembly may further include respective temperature sensors thermally coupled to respective sensors. The controller may be further programmed to activate the fan upon receiving data from at least one of the temperature sensors indicating a temperature above the threshold. The temperature sensors may be thermocouples.

The housing may be attachable to a vehicle. The housing may include a front side facing forward relative to the vehicle, and the front side may include the opening. The opening may be a first opening, the semipermeable fabric may be a first semipermeable fabric, the housing may include a lateral side facing sideways relative to the vehicle, the lateral side may include a second opening, and the sensor assembly may further include a second semipermeable fabric covering the second opening. The lateral side may be a left lateral side facing leftward relative to the vehicle, the housing may include a right lateral side facing rightward relative to the vehicle, the right lateral side may include a third opening, and the sensor assembly may further include a third semipermeable fabric covering the third opening.

The opening may be a first opening, the housing may include a rear side facing rearward relative to the vehicle, and the rear side may include a second opening. The fan may be adjacent to the second opening.

At least one of the sensors may be closer to the opening than the fan. All the sensors may be closer to the opening than the fan.

The housing may be attachable to a roof of the vehicle.

The opening may be a first opening, the housing may include a second opening, and the fan may be adjacent to the second opening. The fan may be closer to the second opening than to any of the sensors.

The threshold may be a first threshold, and the controller may be programmed to deactivate the fan upon determining that the temperatures of the sensors are below a second threshold that is lower than the first threshold.

The fan may be positioned to direct airflow across all the sensors.

The semipermeable fabric may be waterproof.

The sensors may be cameras.

The housing may include a plurality of portholes, and the sensors may each be aimed at one of the portholes.

With reference to the Figures, a sensor assembly 30 includes a housing 32 defining a cavity 34 that includes a plurality of sensors 36, one of a plurality of semipermeable fabrics 70, 72, 74 covering one of a plurality of openings 40, 42, 44, 46 in the cavity 34, a fan 48 positioned to direct airflow through the one of the openings 40, 42, 44, 46, and a controller 50 programmed to activate the fan 48 upon determining that a temperature of at least one sensor 36 is above a threshold.

The sensor assembly 30 provides active cooling of the sensors 36 to prevent or reduce overheating of the sensors 36 for a vehicle 52. The active cooling can be achieved in an efficient manner by using air from the ambient environment. The semipermeable fabrics 70, 72, 74 provide filtering by allowing airflow while blocking debris and moisture from the environment.

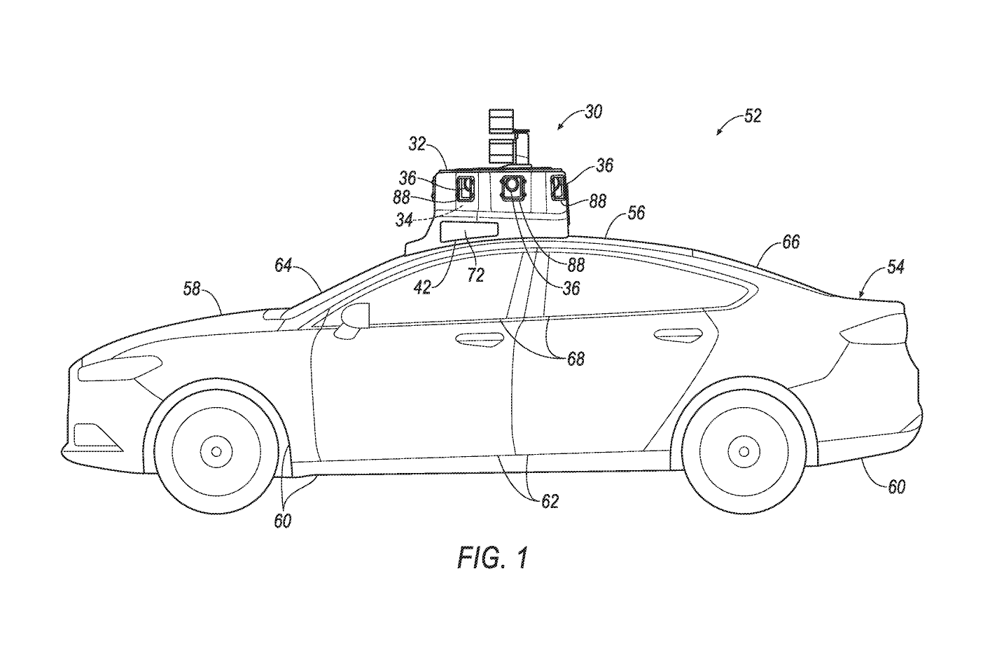

With reference to FIG. 1, the vehicle 52 may be an autonomous vehicle. A computer can be configured to operate the vehicle 52 independently of the intervention of a human driver, completely or to a lesser degree. The computer may be programmed to operate the propulsion, brake system, steering, and/or other vehicle systems. For the purposes of this disclosure, autonomous operation means the computer controls the propulsion, brake system, and steering; semi-autonomous operation means the computer controls one or two of the propulsion, brake system, and steering and a human driver controls the remainder; and nonautonomous operation means the human driver controls the propulsion, brake system, and steering.

The vehicle 52 includes a body 54. The vehicle 52 may be of a unibody construction, in which a frame and the body 54 of the vehicle 52 are a single component, as shown in FIG. 1. The vehicle 52 may, alternatively, be of a body-on-frame construction, in which a frame (not shown) supports a body 54 that is a separate component from the frame. The frame and the body 54 may be formed of any suitable material, for example, steel, aluminum, etc.

The body 54 includes body panels 56, 58, 60 partially defining an exterior of the vehicle 52. The body panels 56, 58, 60 may present a class-A surface, e.g., a finished surface exposed to view by a customer and free of unaesthetic blemishes and defects. The body panels 56, 58, 60 include, e.g., a roof 56, a hood 58, etc. Doors 62 may be movably mounted to the body 54.

The body 54 supports windows 64, 66, 68, including, e.g., a windshield 64, a backlite 66, and side windows 68. The windows 64, 66, 68 may be formed of any suitably durable transparent material, including glass such as laminated, tempered glass or plastic such as Plexiglas® or polycarbonate.

For the purposes of this disclosure, an “exterior surface” of the vehicle 52 is a surface disposed on an outside of the vehicle 52 and facing away from the vehicle 52. For example, the body panels 56, 58, 60 and the windows 64, 66, 68 are exterior surfaces 56, 58, 62, 64, 66, 68. The roof 56 is one of the exterior surfaces 56, 58, 62, 64, 66, 68.

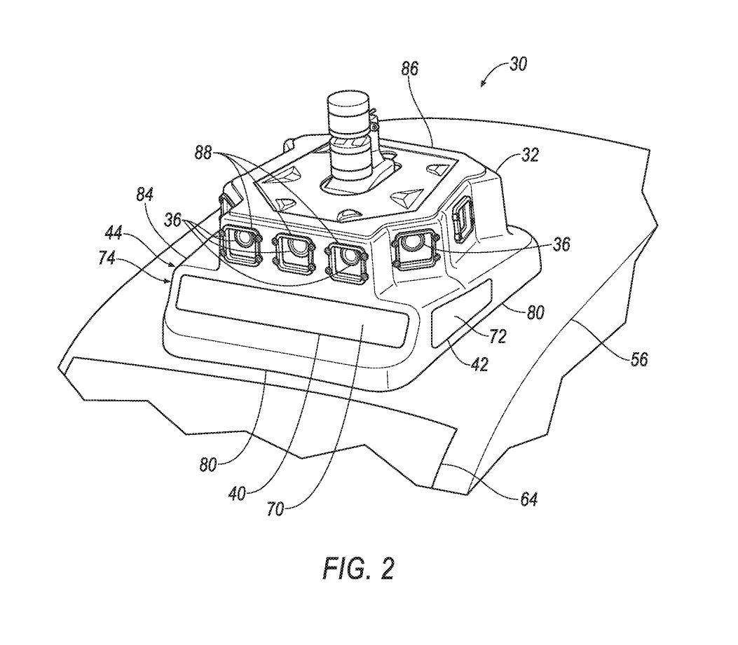

With reference to FIG. 2, the housing 32 for the sensors 36 is attachable to the vehicle 52, e.g., to one of the exterior surfaces 56, 58, 62, 64, 66, 68 of the vehicle 52, e.g., the roof 56. The housing 32 may be attached to the roof 56, which can provide the sensors 36 with an unobstructed field of view of an area around the vehicle 52. The housing 32 may be formed of, e.g., plastic or metal.

The housing 32 may enclose and define the cavity 34; for example, the housing 32 may define a top and sides of the cavity 34. One or more of the exterior surfaces 56, 58, 62, 64, 66, 68, e.g., the roof 56, may partially define the cavity 34, or the housing 32 may define a bottom of the cavity 34 as well as a top of the cavity 34. The housing 32 may shield contents of the cavity 34 from external elements such as wind, rain, debris, etc.

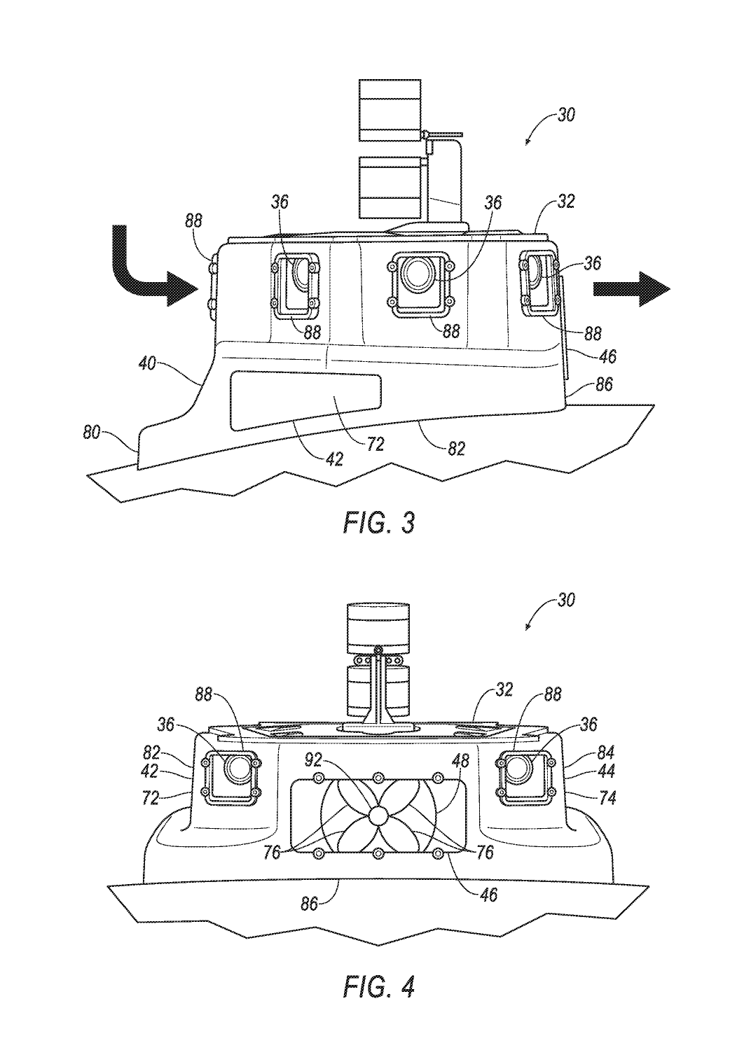

With reference to FIGS. 2-4, the housing 32 includes a front side 80 facing forward relative to the vehicle 52; a left lateral side 82 facing leftward, i.e., sideways toward the left, relative to the vehicle 52; a right lateral side 84 facing rightward, i.e., sideways toward the right, relative to the vehicle 52; and a rear side 86 facing rearward relative to the vehicle 52.

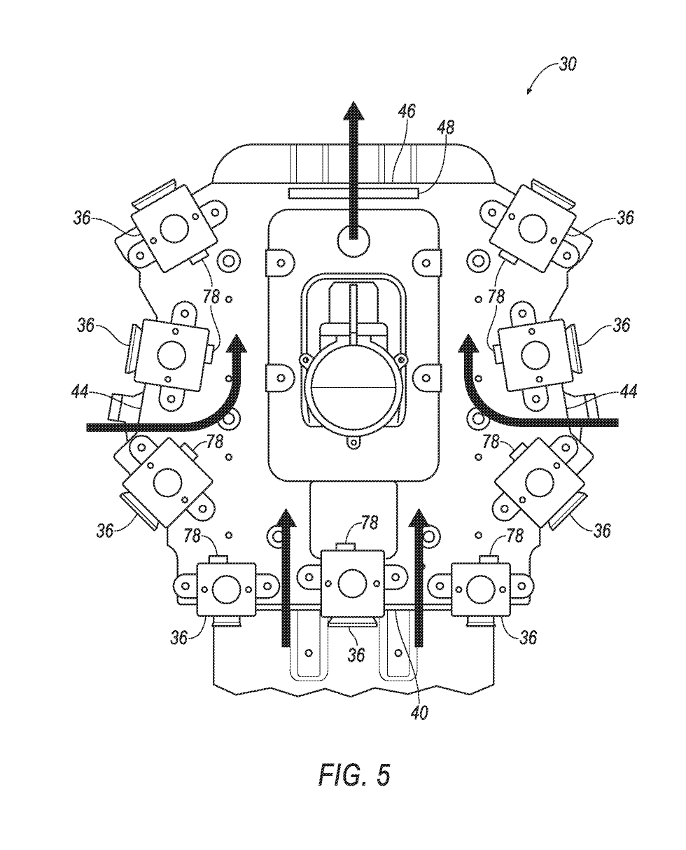

With reference to FIG. 5, the cavity 34 includes the sensors 36. The sensors 36 may be attached directly to the roof 56 in the cavity 34, or the sensors 36 may be attached to the housing 32 in the cavity 34, which in turn is directly attached to the roof 56. The sensors 36 are disposed inside the housing 32, i.e., in the cavity 34. The housing 32 may include one or more portholes 88, and the sensors 36 are each aimed at one of the portholes 88 and may each have a field of view through one of the portholes 88.

The sensors 36 may detect the location and/or orientation of the vehicle 52. For example, the sensors 36 may include global positioning system (GPS) sensors; accelerometers such as piezo-electric or microelectromechanical systems (MEMS); gyroscopes such as rate, ring laser, or fiber-optic gyroscopes; inertial measurements units (IMU); and magnetometers. The sensors 36 may detect the external world, e.g., objects and/or characteristics of surroundings of the vehicle 52, such as other vehicles, road lane markings, traffic lights and/or signs, pedestrians, etc. For example, the sensors 36 may include radar sensors, scanning laser range finders, light detection and ranging (LIDAR) devices, and image processing sensors such as cameras. The sensors 36 may include communications devices, for example, vehicle-to-infrastructure (V2I) or vehicle-to-vehicle (V2V) devices. In particular, the sensors 36 may be cameras arranged to collectively cover a 360° horizontal field of view.

With reference to FIGS. 2-4, the housing 32 includes the openings 40, 42, 44, 46 to the cavity 34. For example, the front side 80 may include a first opening 40, the left lateral side 82 may include a second opening 42, the right lateral side 84 may include a third opening 44, and the rear side 86 may include a fourth opening 46. (The adjectives “first,” “second,” “third,” and “fourth” are used throughout this document as identifiers and are not intended to signify importance or order.) The openings 40, 42, 44, 46 permit airflow between the cavity 34 and the ambient environment. The openings 40, 42, 44, 46 may be at least twice as long horizontally as vertically. The openings 40, 42, 44, 46 may be rectangular in shape.

A first semipermeable fabric 70 may cover the first opening 40, a second semipermeable fabric 72 may cover the second opening 42, and a third semipermeable fabric 74 may cover the third opening 44. For the purposes of this disclosure, “cover” means extend substantially completely across. The semipermeable fabrics 70, 72, 74 may completely cover their respective openings 40, 42, 44. The semipermeable fabrics 70, 72, 74 may prevent airflow through their respective openings 40, 42, 44 other than through the semipermeable fabrics 70, 72, 74. The fourth opening 46 may lack a semipermeable fabric.

For the purposes of this disclosure, “semipermeable fabric” means a fabric that repels liquid water and allows air and water vapor to pass through. The semipermeable fabrics 70, 72, 74 may be formed of a layer of fibers of stretched polytetrafluoroethylene (PTFE), as well as possibly other layers. An example of a semipermeable fabric is GORE-TEX®. The semipermeable fabrics 70, 72, 74 are waterproof.

With reference to FIG. 4, the fan 48 includes a plurality of blades 76 that are, e.g., radially arranged and rotatable together to generate airflow. The fan 48 may include a motor 92 for driving the blades 76, e.g., rotationally.

With reference to FIG. 5, the fan 48 is disposed in the cavity 34. The fan 48 is adjacent to the fourth opening 46; i.e., nothing is disposed between the fan 48 and the fourth opening 46. The fan 48 is closer to the fourth opening 46 than any of the sensors 36 is, and the fan 48 is closer to the fourth opening 46 than to any of the sensors 36. All the sensors 36 are closer to the first opening 40 than is the fan 48. At least one of the sensors 36 is closer to each of the first opening 40, the second opening 42, and the third opening 44 than the fan 48 is. The fan 48 is more rearward relative to the vehicle 52 than are any of the sensors 36.

The fan 48 is positioned to direct airflow into the cavity 34 through the first opening 40, the second opening 42, and the third opening 44, across all the sensors 36, and out of the cavity 34 through the fourth opening 46. Movement of the vehicle 52 may also increase airflow into the cavity 34 through the first opening 40, across the sensors 36, and out of the cavity 34 through the fourth opening 46.

Respective temperature sensors 78 are thermally coupled to the respective sensors 36; i.e., each of the temperature sensors 78 is thermally coupled to a different one of the sensors 36. For the purposes of this disclosure, “thermally coupled” means attached such that heat may efficiently flow and both ends of the thermal coupling (if separate) are substantially the same temperature. The respective temperature sensors 78 are positioned to detect respective temperatures of the respective sensors 36.

The temperature sensors 78 each detect a temperature of a surrounding environment or an object in contact with the temperature sensor 78. The temperature sensor 78 may be any device that generates an output correlated with temperature, e.g., a thermometer, a bimetallic strip, a thermistor, a thermocouple, a resistance thermometer, a silicon bandgap temperature sensor, etc. In particular, the temperature sensors 78 may be thermocouples.

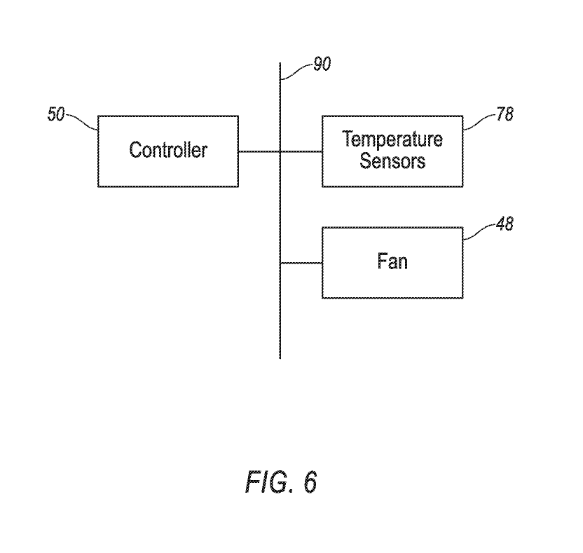

With reference to FIG. 6, the vehicle 52 may include the controller 50. The controller 50 is a microprocessor-based controller. The controller 50 includes a processor, memory, etc. The memory of the controller 50 includes memory for storing instructions executable by the processor as well as for electronically storing data and/or databases. The controller 50 may be the same as the computer for autonomously or semi-autonomously operating the vehicle 52, or the controller 50 may be a different computer than the computer for autonomously or semi-autonomously operating the vehicle 52.

The controller 50 may transmit and receive data through a communications network 90 such as a controller area network (CAN) bus, Ethernet, WiFi, Local Interconnect Network (LIN), onboard diagnostics connector (OBD-II), and/or by any other wired or wireless communications network. The controller 50 may be in communication with the fan 48 and the temperature sensors 78, as well as possibly other components, via the communications network 90.

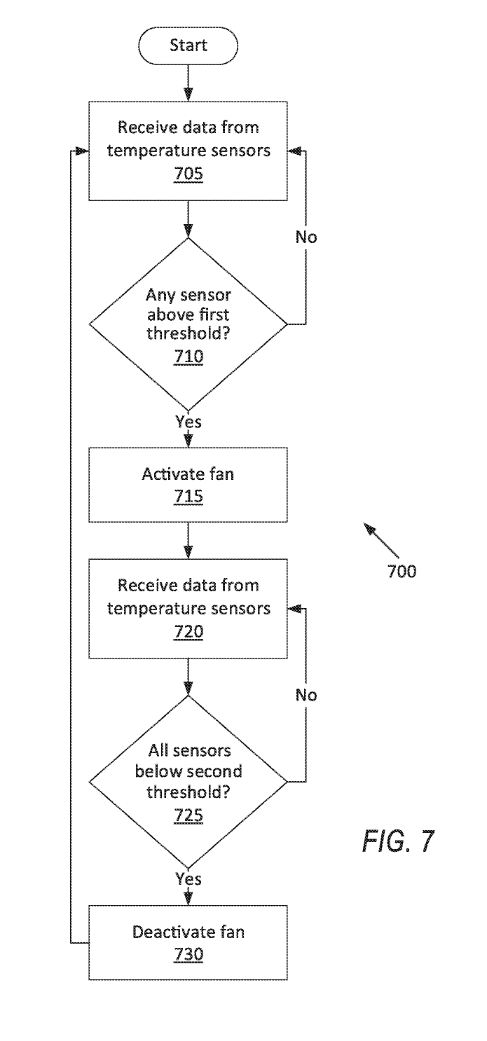

FIG. 7 is a process flow diagram illustrating an exemplary process 700 for regulating the temperatures of the sensors 36 of the sensor assembly 30. In general, as described in more detail below, the controller 50 is programmed to activate the fan 48 upon determining that a temperature of at least one sensor 36 is above a first threshold and deactivate the fan 48 upon determining that the temperatures of all the sensors 36 are below a second threshold. The sensor assembly 30 thus provides active cooling to keep all the sensors 36 within a range of temperatures below the first threshold and generally above the second threshold. The memory of the controller 50 stores executable instructions for performing the steps of the process 700.

The process 700 begins in a block 705, in which the controller 50 receives data from the temperature sensors 78 indicating the temperatures of each of the sensors 36. The data may include the temperatures in any units of temperature, e.g., Fahrenheit or Celsius, or in units of another quantity that is correlated with temperature, e.g., volts if the temperature sensors 78 are thermocouples.

Next, in a decision block 710, the controller 50 determines whether a temperature of at least one sensor 36 is above the first threshold based on the data from the temperature sensors 78. The first threshold is chosen to be below a temperature at which the sensors 36 may overheat and/or malfunction. The first threshold is typically expressed in the same units as the data indicating the temperatures of the sensors 36. The first threshold may be the same regardless of which of the sensors 36 exceeds the first threshold. If all the temperatures of the sensors 36 are below the first threshold, the process 700 returns to the block 705 to continue monitoring the temperatures of the sensors 36.

Next, if the temperature of at least one of the sensors 36 is above the first threshold, in a block 715, the controller 50 activates the fan 48. The controller 50 instructs the motor 92 of the fan 48 to rotate the blades 76 so that air is drawn in through the first opening 40, the second opening 42, and the third opening 44; travels across the sensors 36; and exits through the fourth opening 46.

Next, in a block 720, the controller 50 receives data from the temperature sensors 78 indicating the temperatures of each of the sensors 36, as described above with respect to the block 705.

Next, in a decision block 725, the controller 50 determines whether the temperatures of all the sensors 36 are below the second threshold based on the data from the temperature sensors 78. The second threshold is chosen to be above a temperature at which the sensors 36 may operate inefficiently or sluggishly from being too cold and sufficiently far from the first threshold that the fan 48 does not turn on and off too frequently, e.g., at a frequency that causes the fan 48 to wear out too quickly. The second threshold is typically expressed in the same units as the data indicating the temperatures of the sensors 36. If at least one of the temperatures of the sensors 36 is above the second threshold, the process 700 returns to the block 720 to continue monitoring the temperatures of the sensors 36 while cooling the sensors 36 by running the fan 48.

Next, if the temperatures of all the sensors 36 are below the second threshold, the controller 50 deactivates the fan 48. The controller 50 instructs the motor 92 of the fan 48 to cease rotating so that the fan 48 is no longer contributing to the airflow through the cavity 34. Airflow may still be caused by the motion of the vehicle 52. After the block 730, the process returns to the block 705 to continue monitoring the temperatures of the sensors 36.

In general, the computing systems and/or devices described may employ any of a number of computer operating systems, including, but by no means limited to, versions and/or varieties of the Ford Sync® application, AppLink/Smart Device Link middleware, the Microsoft Automotive® operating system, the Microsoft Windows® operating system, the Unix operating system (e.g., the Solaris® operating system distributed by Oracle Corporation of Redwood Shores, Calif.), the AIX UNIX operating system distributed by International Business Machines of Armonk, N.Y., the Linux operating system, the Mac OSX and iOS operating systems distributed by Apple Inc. of Cupertino, Calif., the BlackBerry OS distributed by Blackberry, Ltd. of Waterloo, Canada, and the Android operating system developed by Google, Inc. and the Open Handset Alliance, or the QNX® CAR Platform for Infotainment offered by QNX Software Systems. Examples of computing devices include, without limitation, an on-board vehicle computer, a computer workstation, a server, a desktop, notebook, laptop, or handheld computer, or some other computing system and/or device.

Computing devices generally include computer-executable instructions, where the instructions may be executable by one or more computing devices such as those listed above. Computer executable instructions may be compiled or interpreted from computer programs created using a variety of programming languages and/or technologies, including, without limitation, and either alone or in combination, Java™, C, C++, Matlab, Simulink, Stateflow, Visual Basic, Java Script, Perl, HTML, etc. Some of these applications may be compiled and executed on a virtual machine, such as the Java Virtual Machine, the Dalvik virtual machine, or the like. In general, a processor (e.g., a microprocessor) receives instructions, e.g., from a memory, a computer readable medium, etc., and executes these instructions, thereby performing one or more processes, including one or more of the processes described herein. Such instructions and other data may be stored and transmitted using a variety of computer readable media. A file in a computing device is generally a collection of data stored on a computer readable medium, such as a storage medium, a random access memory, etc.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random access memory (DRAM), which typically constitutes a main memory. Such instructions may be transmitted by one or more transmission media, including coaxial cables, copper wire and fiber optics, including the wires that comprise a system bus coupled to a processor of a ECU. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

Databases, data repositories or other data stores described herein may include various kinds of mechanisms for storing, accessing, and retrieving various kinds of data, including a hierarchical database, a set of files in a file system, an application database in a proprietary format, a relational database management system (RDBMS), etc. Each such data store is generally included within a computing device employing a computer operating system such as one of those mentioned above, and are accessed via a network in any one or more of a variety of manners. A file system may be accessible from a computer operating system, and may include files stored in various formats. An RDBMS generally employs the Structured Query Language (SQL) in addition to a language for creating, storing, editing, and executing stored procedures, such as the PL/SQL language mentioned above.

In some examples, system elements may be implemented as computer-readable instructions (e.g., software) on one or more computing devices (e.g., servers, personal computers, etc.), stored on computer readable media associated therewith (e.g., disks, memories, etc.). A computer program product may comprise such instructions stored on computer readable media for carrying out the functions described herein.

In the drawings, the same reference numbers indicate the same elements. Further, some or all of these elements could be changed. With regard to the media, processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

All terms used in the claims are intended to be given their plain and ordinary meanings as understood by those skilled in the art unless an explicit indication to the contrary in made herein. In particular, use of the singular articles such as “a,” “the,” “said,” etc. should be read to recite one or more of the indicated elements unless a claim recites an explicit limitation to the contrary. Use of “in response to” and “upon determining” indicates a causal relationship, not merely a temporal relationship.

The disclosure has been described in an illustrative manner, and it is to be understood that the terminology which has been used is intended to be in the nature of words of description rather than of limitation. Many modifications and variations of the present disclosure are possible in light of the above teachings, and the disclosure may be practiced otherwise than as specifically described.

What is claimed is:

1. A sensor assembly, comprising:
a housing defining a cavity that includes a plurality of sensors;
a semipermeable fabric covering an opening in the cavity;
a fan positioned to direct airflow through the opening; and
a controller programmed to activate the fan upon determining that a temperature of at least one sensor is above a threshold.

2. The sensor assembly of claim 1, further comprising respective temperature sensors thermally coupled to respective sensors.

3. The sensor assembly of claim 2, wherein the controller is further programmed to activate the fan upon receiving data from at least one of the temperature sensors indicating a temperature above the threshold.

4. The sensor assembly of claim 2, wherein the temperature sensors are thermocouples.

5. The sensor assembly of claim 1, wherein the housing is attachable to a vehicle.

6. The sensor assembly of claim 5, wherein the housing includes a front side facing forward relative to the vehicle, and the front side includes the opening.

7. The sensor assembly of claim 6, wherein the opening is a first opening, the semipermeable fabric is a first semipermeable fabric, the housing includes a lateral side facing sideways relative to the vehicle, and the lateral side includes a second opening, the sensor assembly further comprising a second semipermeable fabric covering the second opening.

8. The sensor assembly of claim 7, wherein the lateral side is a left lateral side facing leftward relative to the vehicle, the housing includes a right lateral side facing rightward relative to the vehicle, and the right lateral side includes a third opening, the sensor assembly further comprising a third semipermeable fabric covering the third opening.

9. The sensor assembly of claim 6, wherein the opening is a first opening, the housing includes a rear side facing rearward relative to the vehicle, and the rear side includes a second opening.

10. The sensor assembly of claim 9, wherein the fan is adjacent to the second opening.

11. The sensor assembly of claim 6, wherein at least one of the sensors is closer to the opening than the fan.

12. The sensor assembly of claim 11, wherein all the sensors are closer to the opening than the fan.

13. The sensor assembly of claim 5, wherein the housing is attachable to a roof of the vehicle.

14. The sensor assembly of claim 1, wherein the opening is a first opening, the housing includes a second opening, and the fan is adjacent to the second opening.

15. The sensor assembly of claim 14, wherein the fan is closer to the second opening than to any of the sensors.

16. The sensor assembly of claim 1, wherein the threshold is a first threshold, and the controller is programmed to deactivate the fan upon determining that the temperatures of the sensors are below a second threshold that is lower than the first threshold.

17. The sensor assembly of claim 1, wherein the fan is positioned to direct airflow across all the sensors.

18. The sensor assembly of claim 1, wherein the semipermeable fabric is waterproof.

19. The sensor assembly of claim 1, wherein the sensors are cameras.

20. The sensor assembly of claim 1, wherein the housing includes a plurality of portholes, and the sensors are each aimed at one of the portholes.
